(19) United States
(12) Patent Application Publication
(10) Pub. No.: US 2025/0224328 A1
(43) Pub. Date: Jul. 10, 2025

(54) DEVICE FOR MEASURING SEMICONDUCTORS

(71) Applicant: Samsung Electronics Co., Ltd., Suwon-si (KR)

(72) Inventors: Sangwoo BAE, Suwon-si (KR); Jangwoon SUNG, Suwon-si (KR); Wookrae KIM, Suwon-si (KR); Hyungjin KIM, Suwon-si (KR); Seungbeom PARK, Suwon-si (KR); Junho SHIN, Suwon-si (KR); Myungjun LEE, Suwon-si (KR); Hojun LEE, Suwon-si (KR)

(73) Assignee: Samsung Electronics Co., Ltd., Suwon-si (KR)

(21) Appl. No.: 18/987,095

(22) Filed: Dec. 19, 2024

(30) Foreign Application Priority Data
Jan. 9, 2024 (KR) 10-2024-0003630

(51) Int. Cl. G01N 21/21; G01B 11/24; G01N 21/88; G01N 21/95

(52) U.S. Cl. CPC G01N 21/211; G01B 11/2441; G01N 21/8806; G01N 21/9501; G01B 2210/56; G01B 2290/70; G01N 2021/8848

(57) ABSTRACT

A semiconductor measurement device includes a first light source unit including a plurality of first point light sources configured to generate first input light, a first relay lens on a path of the first input light, an objective lens configured to make the first input light having passed through the first relay lens incident on a sample, a meta surface structure on a path of the first input light having passed through the objective lens and configured to separate the first input light into a first input polarization component and a second input polarization component, and a detector.

### CROSS-REFERENCE TO RELATED APPLICATION

This application is based on and claims priority under 35 U.S.C. § 119 to Korean Patent Application No. 10-2024-0003630, filed on Jan. 9, 2024, in the Korean Intellectual Property Office, the disclosure of which is incorporated by reference herein in its entirety.

### BACKGROUND

The inventive concepts relate to a device for measuring semiconductors (hereinafter referred to as a semiconductor measurement device), and more particularly, to a semiconductor measurement device including a meta surface structure.

In semiconductor manufacturing processes, it is often necessary to measure the shape of a three-dimensional structure formed on a wafer, which affects device performance. Measurement devices, such as atomic force microscope (AMF) and white light interferometry (WLI), are used to measure a surface profile, for example, topography, including height information of a sample, but there are problems in that the accuracy of the information is low, information on the physical properties of the sample is difficult to measure, and/or the measurement is slow. Therefore, alternative measurement devices are being explored.

### SUMMARY

The inventive concepts provide a measurement device having improved reliability, which may precisely measure the three-dimensional surface structure and physical properties of a sample.

According to an aspect of the inventive concepts, there is provided a semiconductor measurement device including a first light source unit including a plurality of first point light sources configured to generate a first input light; a first relay lens in a path of the first input light; an objective lens in a path of the first input light having passed through the first relay lens, the objective lens configured to make the first input light incident to a sample; a meta surface structure in a path of the first input light having passed the objective lens, the meta surface structure configured to separate the first input light into a first input polarization component and a second input polarization component, to separate first reflected light, generated when the first input polarization component is reflected by the sample, into a first reflected polarization component and a second reflected polarization component, and to separate second reflected light, generated when the second input polarization component is reflected by the sample, into a third reflected polarization component and a fourth reflected polarization component; and a detector configured to detect the first reflected polarization component, the second reflected polarization component, the third reflected polarization component, and the fourth reflected polarization component.

According to another aspect of the inventive concepts, there is provided a semiconductor measurement device including a first light source unit including a plurality of first point light sources configured to generate first input light; a first relay lens in a path of the first input light; a meta surface structure configured to transmit the first input light having passed through the first relay lens to a sample and to separate the first input light into a first input polarization component and a second input polarization component; and a second light source unit around the meta surface structure, the second light source unit including a plurality of second point light sources configured to generate second input light having an incident angle with respect to the sample, the incident angle of the second input light being different from an incident angle of the first input light with respect to the sample.

According to another aspect of the inventive concepts, there is provided a semiconductor measurement device including a first light source unit including a plurality of first point light sources spaced apart from each other and each configured to generate first input light; a first relay lens in a path of the first input light; an objective lens configured to collimate the first input light having passed through the first relay lens and make the collimated first input light incident to a sample; a second light source unit around the objective lens and including a plurality of second point light sources each configured to generate second input light having an incident angle with respect to the sample, the incident angle of the second input light being different from an incident angle of the first input light with respect to the sample; a meta surface structure in the path of the first input light having passed through the objective lens and a path of the second input light such that the meta surface structure is configured to separate the first input light into a first input polarization component and a second input polarization component, to separate the second input light into a third input polarization component and a fourth input polarization component, to separate first reflected light, generated when the first input polarization component is reflected by the sample, into a first reflected polarization component and a second reflected polarization component, and to separate second reflected light, generated when the second input polarization component is reflected by the sample, into a third reflected polarization component and a fourth reflected polarization component; and a detector configured to detect the first reflected polarization component, the second reflected polarization component, the third reflected polarization component, and the fourth reflected polarization component.

### BRIEF DESCRIPTION OF THE DRAWINGS

Embodiments will be more clearly understood from the following detailed description taken in conjunction with the accompanying drawings in which:

FIG. 1 is a schematic structural diagram of a semiconductor measurement device according to embodiments;

FIG. 2A is a plan view illustrating a first light source unit of a semiconductor measurement device according to embodiments;

FIG. 2B is a plan view illustrating a second light source unit of a semiconductor measurement device according to embodiments;

FIG. 3A is a schematic structural diagram showing a partial configuration of a semiconductor measurement device to explain the path of first input light in a semiconductor measurement device according to embodiments;

FIG. 3B is a schematic structural diagram showing a partial configuration of a semiconductor measurement device to explain the path of second input light in a semiconductor measurement device according to embodiments;

FIG. 3C is a schematic structural diagram showing a partial configuration of a semiconductor measurement device to explain the path of reflected light in a semiconductor measurement device according to embodiments;

FIGS. 4A and 4B are a diagram illustrating a meta surface structure according to embodiments, wherein FIG. 4A is a perspective view of a meta atom, and FIG. 4B is a plan view of the meta atom;

FIG. 5 is a schematic cross-sectional view of a meta surface structure, for illustrating the ability of the meta surface structure to provide a phase gradient, according to embodiments;

FIGS. 6A through 6C are a diagram for explaining changes in polarization and Fourier spectrum of input light as the input light passes through a meta surface structure, wherein FIG. 6A shows a Fourier spectrum obtained from reflected light formed when input light that does not pass through the meta surface structure is reflected from a sample, and FIG. 6B and FIG. 6B each show a Fourier spectrum obtained from reflected light formed when input light passing through the meta surface structure is reflected from the sample;

FIG. 7 is a diagram illustrating an optical system simulation method of a semiconductor measurement device according to embodiments;

FIG. 8 is a schematic structural diagram illustrating a measurement device according to some embodiments;

FIG. 9 is a schematic structural diagram illustrating a measurement device according to some embodiments; and

FIG. 10 is a flowchart illustrating a measurement method according to embodiments.

### DETAILED DESCRIPTION OF THE EMBODIMENTS

Hereinafter, embodiments of the inventive concepts will be described in detail with reference to the accompanying drawings. The same reference numerals are used for the same components in the drawings, and duplicate descriptions thereof are omitted. In the drawings, the size or thickness of each element may be exaggerated for clarity of illustration. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric terms.

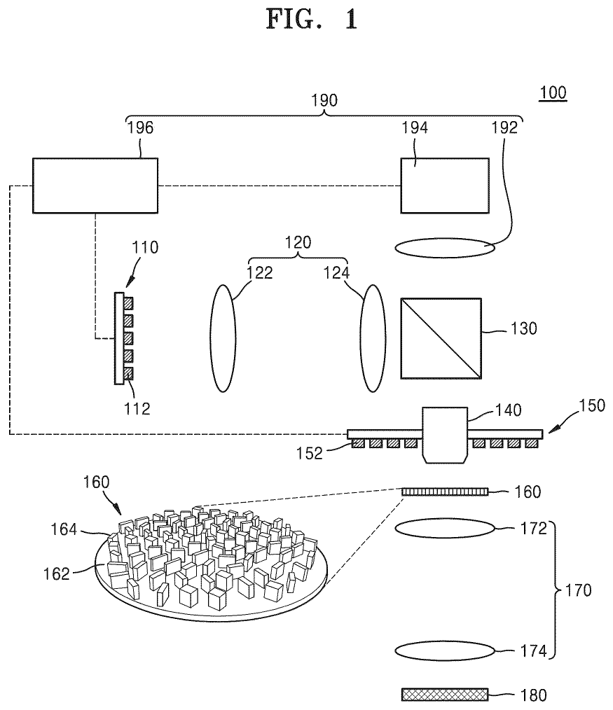

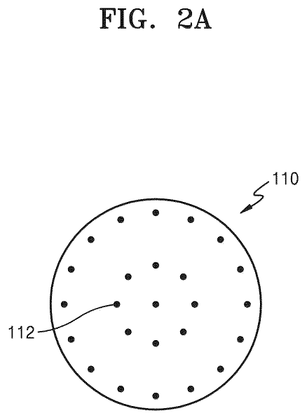

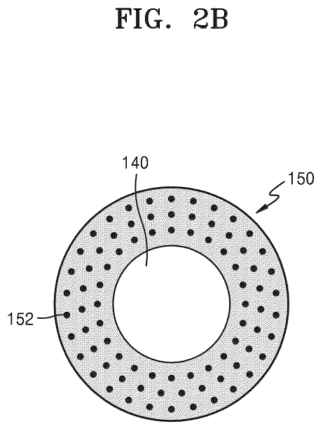

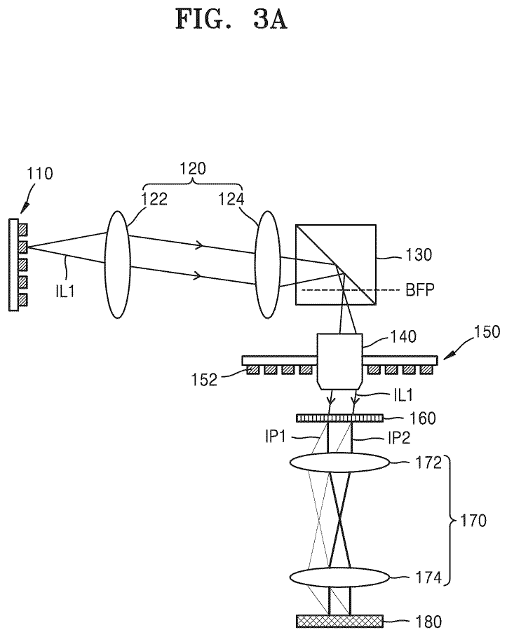

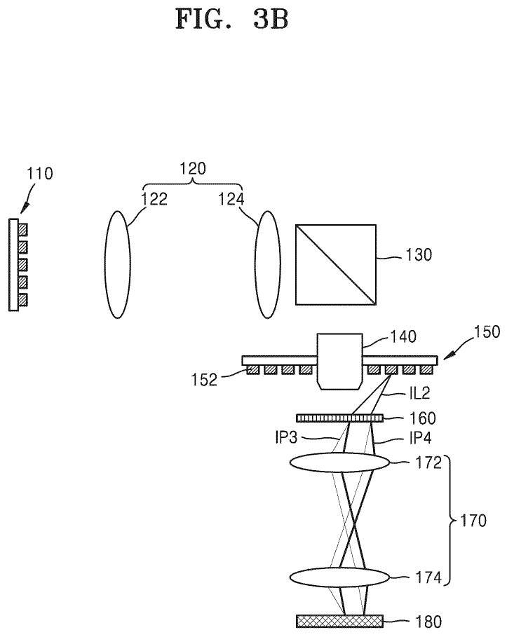

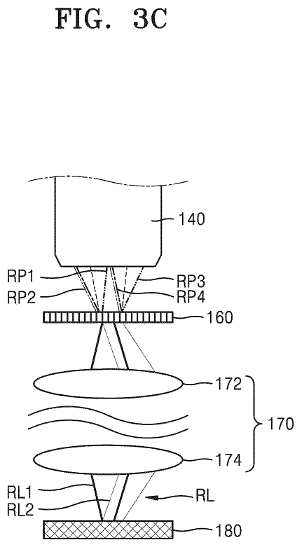

FIG. 1 is a schematic structural diagram of a semiconductor measurement device 100 according to example embodiments. FIG. 2A is a plan view illustrating a first light source unit 110 of the semiconductor measurement device 100 according to example embodiments. FIG. 2B is a plan view illustrating a second light source unit 150 of the semiconductor measurement device 100 according to example embodiments. FIG. 3A is a schematic structural diagram showing a partial configuration of the semiconductor measurement device 100 to explain the path of first input light IL1 in the semiconductor measurement device 100 according to example embodiments. FIG. 3B is a schematic structural diagram showing a partial configuration of the semiconductor measurement device 100 to explain the path of second input light IL2 in the semiconductor measurement device 100 according to example embodiments. In FIGS. 3A and 3B, a detector 190 in FIG. 1 is not shown for convenience. FIG. 3C is a schematic structural diagram showing a partial configuration of the semiconductor measurement device 100 to explain the path of reflected light RL in the semiconductor measurement device 100 according to example embodiments. In FIGS. 3A to 3C, for convenience, components other than an objective lens 140, a meta surface structure 160, a second relay lens 170, and a sample 180 are not shown.

Referring to FIGS. 1 to 3C, the semiconductor measurement device 100 may include a first light source unit 110, a first relay lens 120, a beam splitter 130, the objective lens 140, the second light source unit 150, the meta surface structure 160, a second relay lens 170, a tube lens 192, and the detector 190. The detector 190 may include an image sensor 194, and a processor 196. In at least one embodiment, detector 190 may further include the tube lens 192.

According to example embodiments, the first light source unit 110 may be configured to generate first input light IL1 having different incident angles with respect to the sample 180. For ease of description, the first input light IL1 may be described as comprising pieces (of first input light IL1) having different incident angles. In some embodiments, the first light source unit 110 may include a plurality of first point light sources 112 arranged in a two-dimensional array. Referring to FIG. 2A, the plurality of first point light sources 112 may be arranged to be apart from each other and may each be configured to generate first input light IL1 for irradiating the sample 180.

The pieces of first input light IL1 derived from the plurality of first point light sources 112 spaced apart from each other may, therefore, have different incident angles with respect to the sample 180. In at least one embodiment, the plurality of first point light sources 112 of the first light source unit 110 may be configured to sequentially generate the first input light IL1 one by one. For example, one selected from among the plurality of first point light sources 112 may be turned on to generate the first input light IL1 having a first incident angle and then turned off, another one selected from among the plurality of first point light sources 112 may then be turned on to generate the first input light IL1 having a second incident angle and then turned off, and a series of processes may be performed on the remaining first point light sources 112 as well. The detector 190 may be configured to detect the reflected light RL formed when each of the pieces of first input light IL1 is reflected by the sample 180.

In some embodiments, each of the plurality of first point light sources 112 may be a light-emitting diode (LED), and the first light source unit 110 may include an LED array. However, the type of light source is limited to the above-described example. For example, the plurality of first point light sources 112 may each include a laser light source, a variable wavelength light source, a broadband light source, and/or the like. In at least some embodiment, each of the plurality of first point light sources 112 may be configured to produce the same wavelength (or wavelengths) of light.

In some embodiments, the first light source unit 110 may include an optical grating, a wavefront modulator, or a digital micro-mirror device (DMD) that may cause a change in the incident angle of the first input light IL1.

Referring to FIGS. 1 and 3A, the first relay lens 120 may be in the path of the first input light IL1. For example, the first relay lens 120 may include a first lens 122 and a second lens 124 that are apart from each other in the path of the first input light IL1.

According to example embodiments, the first lens 122 may be configured to collimate the first input light IL1 so that the first input light IL1 becomes parallel and/or substantially parallel light (hereafter ‘parallel light’). For example, the first input light IL1 that has passed through the first lens 122 may be parallel light. The second lens 124 may be configured to condense the first input light IL1 that has passed through the first lens 122.

According to some example embodiments, the first input light IL1 that has passed through the first relay lens 120 may be transmitted to the beam splitter 130. The beam splitter 130 may be configured to reflect the first input light IL1 from the first relay lens 120 and transmit the first input light IL1 to the objective lens 140.

According to some example embodiments, the objective lens 140 may be configured to collimate and pass the first input light IL1 from the beam splitter 130. For example, the first input light IL1 that has passed through the objective lens 140 may be parallel light. In some embodiments, the objective lens 140 may have a back focal plane BFP between the objective lens 140 and the first relay lens 120. For example, the parallel light collimated by the first lens 122 of the first relay lens 120 and the parallel light collimated by the objective lens 140 may be in a conjugate relationship.

According to some example embodiments, the collimated first input light IL1 from the objective lens 140 may be transmitted to the meta surface structure 160. According to some example embodiments, the meta surface structure 160 may be configured to separate the first input light IL1 from the objective lens 140 into a first input polarization component IP1 and a second input polarization component IP2.

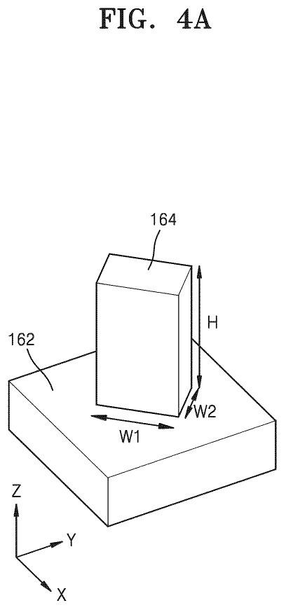

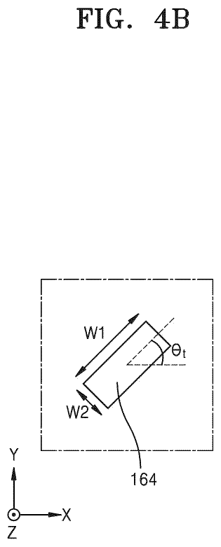

FIGS. 4A and 4B are a diagram illustrating the meta surface structure 160 according to some example embodiments. FIG. 4A is a perspective view of a meta atom 164, and FIG. 4B is a plan view of the meta atom 164.

Referring to FIGS. 1, 4A, and 4B, the meta surface structure 160 may include a transparent substrate 162 and a plurality of meta atoms 164 disposed on the transparent substrate 162. The meta surface structure 160 including the transparent substrate 162 and the plurality of meta atoms 164 is shown in FIG. 1, and FIG. 4 shows a detailed perspective view and plan view of one of the plurality of meta atoms 164 included in the meta surface structure 160. In the present specification, meta atoms represent individual meta structures and may be referred to as polarizing nanostructures.

In some embodiments, the transparent substrate 162 may include a quartz substrate, a glass substrate, a transparent plastic substrate, and/or the like. In some embodiments, the plurality of meta atoms 164 may include a dielectric material that may reduce optical loss. For example, the plurality of meta atoms 164 may include at least one selected from titanium dioxide (TiO), gallium nitride (GaN), silicon nitride (SiN), silicon (Si), and/or the like. Terms such as “TiO,” “GaN,” and “SiN” used in the present specification refer to materials composed of elements included in each term, and are not chemical formulas representing stoichiometric relationships. Further, silicon (Si) may include crystalline silicon and amorphous silicon.

In some embodiments, each of the plurality of meta atoms 164 may have a pillar shape, for example, a quadrangular pillar shape. Referring to FIG. 4, the unit meta atom 164 may have a rectangular planar shape having two sides orthogonal to each other and may have a height H that is a length in a vertical direction (a Z direction), which is a direction perpendicular to the upper surface of the transparent substrate 162. In some embodiments, the first side of the rectangular planar shape may have a first width W1, and the second side of the rectangular planar shape may have a second width W2.

In some embodiments, the first width W1 and the second width W2 may each independently be from about 50 nm to about 300 nm, and the height H may be from about 100 nm to about 1500 nm. However, the disclosure is not limited thereto.

Referring to FIG. 4B, in a plan view, the first side of the unit meta atom 164 may have a tilting angle θₜ with respect to a first horizontal direction (an X direction). In some embodiments, at least some selected from among the plurality of meta atoms 164 disposed on the transparent substrate 162 may have different tilt angles θₜ. In some other embodiments, the plurality of meta atoms 164 may have the same tilting angle θₜ.

In some embodiments, the plurality of meta atoms 164 disposed on the transparent substrate 162 may have the same size. For example, the first sides of the plurality of meta atoms 164 may have the same first width W1, the second sides of the plurality of meta atoms 164 may have the same second width W2, and the plurality of meta atoms 164 may have the height H.

In some other embodiments, at least some of the plurality of meta atoms 164 disposed on the transparent substrate 162 may have different sizes. For example, the length of the first and/or second sides of some of the plurality of meta atoms 164 may be different from the lengths of the first and/or second sides of some other of the meta atoms 164. For example, the lengths of some of the plurality of meta atoms 164 in the vertical direction (the Z direction) may be different from the lengths of some other of the plurality of meta atoms 164 in the vertical direction (the Z direction).

In FIG. 4, the first width W1 of the first side of the unit meta atom 164 and the second width W2 of the second side of the unit meta atom 164 are illustrated as being different from each other, but are not limited thereto. For example, the first width W1 and the second width W2 may be equal to each other. For example, in some embodiments, the unit meta atom 164 may be referred to as having a substantially orthorhombic shape, wherein the height H, the first width W1, and the second width W2 are all unequal to each other and/or may be referred to as having a tetragonal shape, wherein one of the height H, the first width W1, and the second width W2 is unequal to the remaining two. In addition, in FIG. 4, the unit meta atom 164 is illustrated as having a quadrangular pillar shape, but is not limited thereto. For example, the unit meta atom 164 may have a cylindrical shape, a pentagonal pillar shape, or the like.

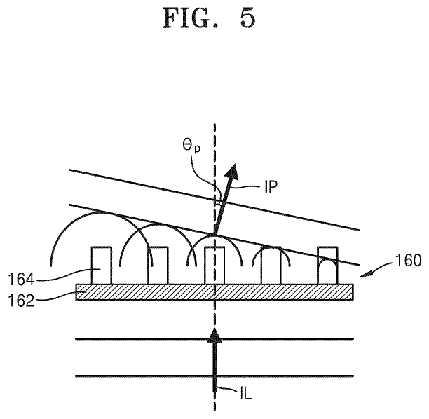

FIG. 5 is a schematic cross-sectional view of the meta surface structure 160 to illustrate the ability of the meta surface structure 160 to provide a phase gradient, according to example embodiments. Input light IL illustrated in FIG. 5 may include, for example, the first input light IL1 transmitted to the meta surface structure 160 through the objective lens 140 in FIG. 3A. Hereinafter, the description will be made with reference to FIGS. 1 to 4B and FIG. 5.

Referring to FIG. 5, the meta surface structure 160 may be configured to provide a phase gradient to the input light IL. According to example embodiments, an input polarization component IP separated by passing through the meta surface structure 160 may have a phase gradient angle θₚ with respect to the input light IL. The phase gradient angle θₚ may vary depending on the first width W1, second width W2, height H, and tilt angle θₜ of each of the plurality of meta atoms 164 and the arrangement of the plurality of meta atoms 164.

According to example embodiments, the meta surface structure 160 may independently provide phase retardation to the first input polarization component IP1 and the second input polarization component IP2. In some embodiments, the meta surface structure 160 may be configured to provide different phase gradient angles θₚ for the first input polarization component IP1 and the second input polarization component IP2. In some other embodiments, the meta surface structure 160 may be configured to provide the same phase gradient angle θₚ to the first input polarization component IP1 and the second input polarization component IP2.

According to example embodiments, the meta surface structure 160 may separate input light into two polarization components having different wavenumbers. In addition, the meta surface structure 160 may include the plurality of meta atoms 164 and independently adjust the phase gradient of the first input polarization component IP1 and the phase gradient of the second input polarization component IP2 based on the input light IL, for example, the first input light IL1. The semiconductor measurement device 100 according to example embodiments may not only separate input light into polarization components, but also independently adjust the phase gradient for each polarization component, thereby variously obtaining surface topology information and physical property information of the sample 180 to be measured (e.g., a semiconductor device). The surface topology information may include a three-dimensional structure of a semiconductor device, and the physical property information may include information about a surface material, for example, information of grain of a copper pad of a semiconductor chip or package or information about stress.

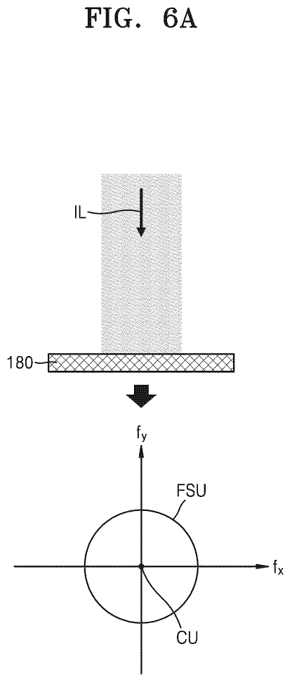

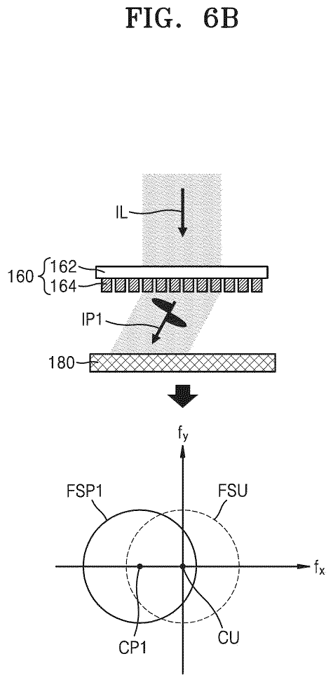

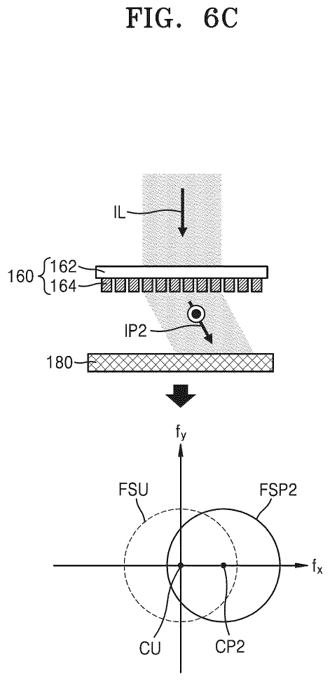

FIGS. 6A to 6C are a diagram for explaining changes in polarization and Fourier spectrum of input light IL as the input light IL passes through the meta surface structure 160. FIG. 6A shows a Fourier spectrum obtained from reflected light formed when input light IL that has not passed through the meta surface structure 160 is reflected from the sample 180, and FIG. 6B and FIG. 6C each show a Fourier spectrum obtained from reflected light formed when input light IL that has passed through the meta surface structure 160 is reflected from the sample 180. The input light IL illustrated in FIGS. 6A to 6C may include, for example, the first input light IL1 transmitted to the meta surface structure 160 through the objective lens 140 in FIG. 3A. Hereinafter, the description will be made with reference to FIGS. 1 to 6C.

Referring to FIG. 6A, in a measurement device according to a comparative example, which does not include the meta surface structure 160, the input light IL is directly transmitted to the sample 180. When the reflected light formed when the input light IL is reflected from the sample 180 is detected and displayed in a Fourier domain, a reference Fourier spectrum FSU of FIG. 6S may be obtained. The reference Fourier spectrum FSU may have a reference center CU. In FIG. 6A, the reference Fourier spectrum FSU is illustrated as having a circular shape in the Fourier domain. However, this is for convenience of explanation, and the inventive concepts are not limited thereto.

Referring to FIG. 6B and FIG. 6C, in the semiconductor measurement device 100 according to example embodiments, which includes the meta surface structure 160, the input light IL may be separated into a first input polarization component IP1 and a second input polarization component IP2 through the meta surface structure 160. The first input polarization component IP1 and the second input polarization component IP2 may be independently reflected from the sample 180, and when the reflected light is detected and displayed in the Fourier domain, a first polarization Fourier spectrum FSP1 having a first center CP1 and a second polarization Fourier spectrum FSP2 having a second center CP2 may be obtained. For example, the first polarization Fourier spectrum FSP1 and the second polarization Fourier spectrum FSP2 may each independently have a shape shifted from the reference Fourier spectrum FSU.

In FIG. 6B and FIG. 6C, the input light IL is separated into two pieces of linearly polarized light perpendicular to each other by the meta surface structure 160. However, the inventive concepts are not limited thereto. In some other embodiments, the first input polarization component IP1 and the second input polarization component IP2 may be elliptically polarized light.

In some other embodiments, the first input polarization component IP1 and the second input polarization component IP2 may be circularly polarized light. In FIG. 6B and FIG. 6C, the first polarization Fourier spectrum FSP1 and the second polarization Fourier spectrum FSP2 are illustrated as being symmetrical with respect to the reference Fourier spectrum FSU. However, the inventive concepts are not limited thereto. For example, in the Fourier domain, the frequency difference between the reference center CU and the first center CP1 may be different from the frequency difference between the reference center CU and the second center CP2.

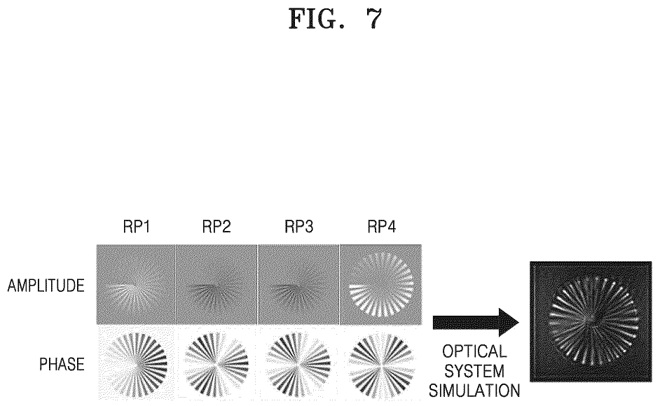

In some embodiments, the pieces of first input light IL1 generated at different times from the plurality of first point light sources 112 of the first light source unit 110 may have different incident angles with respect to the meta surface structure 160. Accordingly, the first polarization Fourier spectrum FSP1 of the first input polarization component IP1 and the second polarization Fourier spectrum FSP2 of the second input polarization component IP2, the first and second input polarization components IP1 and IP2 being separated from each of the pieces of first input light IL1, may also have different regions for each of the pieces of first input light IL1. The first input polarization component IP1 and the second input polarization component IP2 may provide different pieces of optical information, and more diverse optical information may be provided by the pieces of first input light IL1 having different incident angles. In addition, in the semiconductor measurement device 100 according to example embodiments, as described below, the reflected light RL may pass through the meta surface structure 160 to additionally obtain a phase gradient and generate reflected polarization components RP1, RP2, RP3, and RP4 (see FIG. 7). The same principle as described with reference to FIG. 5 may be applied to the Fourier spectra of the reflected polarization components RP1, RP2, RP3, and RP4, and the reflected polarization components RP1, RP2, RP3, and RP4 may have different regions in the Fourier domain of the reflected polarization components RP1, RP2, RP3, and RP4. Accordingly, the semiconductor measurement device 100 may acquire more detailed and diverse optical information, and the surface topology and physical property of the sample 180 may be reconstructed from the more detailed and diverse optical information reflected from the sample 180.

Referring back to FIG. 3A, the first input polarization component IP1 and the second input polarization component IP2 may each be transmitted to the second relay lens 170. In some embodiments, the first input polarization component IP1 and the second input polarization component IP2 may each be parallel light. In some other embodiments, the first input polarization component IP1 and the second input polarization component IP2 may be dispersed light.

In some embodiments, the second relay lens 170 may include a third lens 172 and a fourth lens 174. In some embodiments, the second relay lens 170 may have a focal plane between the third lens 172 and the fourth lens 174. In some embodiments, the first input polarization component IP1 and the second input polarization component IP2 from the second relay lens 170 may be transmitted to the sample 180.

In some other embodiments, the second relay lens 170 may be omitted from the semiconductor measurement device 100. In this case, the first input polarization component IP1 and the second input polarization component IP2 from the meta surface structure 160 may each be directly transmitted to the sample 180.

According to example embodiments, the second light source unit 150 may be configured to generate second input light IL2 having different incident angles with respect to the sample 180 independently of the first light source unit 110. For ease of description, the second input light IL2 may be described as comprising pieces (of second input light IL2) having different incident angles. In some embodiments, the second light source unit 150 may include a plurality of second point light sources 152 arranged in a two-dimensional array. Referring to FIG. 2B, the plurality of second point light sources 152 may be arranged to be apart from each other and may each be configured to generate a second input light IL2 for irradiating the sample 180. The types and functions of the plurality of second point light sources 152 constituting the second light source unit 150 are generally the same as and/or similar to those of the plurality of first point light sources 112 of the first light source unit 110, and thus descriptions thereof are omitted.

As illustrated in FIG. 2B, the second light source unit 150 may be disposed around the objective lens 140 and may have a ring shape in a plan view and be disposed to surround the objective lens 140. Referring to FIGS. 2B and 3B, the pieces of second input light IL2 generated from the plurality of second point light sources 152 may proceed toward the meta surface structure 160. In some embodiments, the pieces of second input light IL2 may be directly transmitted to the meta surface structure 160, and the incident angles of the pieces of second input light IL2 on the meta surface structure 160 may be different from the incident angles of the pieces of first input light IL1 on the meta surface structure 160. Accordingly, the incident angles of the first and second input polarization components IP1 and IP2 on the sample 180 may be different from the incident angles of third and fourth input polarization components IP3 and IP4 on the sample 180. The first and second input polarization components IP1 and IP2 may be separated from the first input light IL1, as described above, and the third and fourth input polarization components IP3 and IP4 may be separated from the second input light IL2, as described below.

In some embodiments, each second input light IL2 may be dispersed light, but the inventive concepts are not limited thereto.

According to example embodiments, the second input light IL2 may pass through the meta surface structure 160 and be separated into the third input polarization component IP3 and the fourth input polarization component IP4. The polarization separation of the input light IL by the meta surface structure 160, described with reference to FIGS. 5 and 6, may also be applied in the same way to the second input light IL2 transmitted from the second light source unit 150 to the meta surface structure 160. For example, the meta surface structure 160 may separate the second input light IL2 into the third input polarization component IP3 and the fourth input polarization component IP4, which have different wavenumbers, and may independently provide a phase gradient for each of the third input polarization component IP3 and the fourth input polarization component IP4. For example, a third Fourier spectrum obtained by detecting reflected light formed from the third input polarization component IP3 may be different from a fourth Fourier spectrum obtained by detecting reflected light formed from the fourth input polarization component IP4, and the third input polarization component IP3 and the fourth input polarization component IP4 may provide different pieces of optical information.

According to example embodiments, the third input polarization component IP3 and the fourth input polarization component IP4 may be transmitted to the second relay lens 170, and the third input polarization component IP3 and the fourth input polarization component IP4 from the second relay lens 170 may be transmitted to the sample 180.

Referring to FIG. 3C, the first input light IL1 or the second input light IL2 may be reflected by the sample 180 to generate reflected light RL.

According to example embodiments, when the first input light IL1 is generated from the first point light source 112, the first input polarization component IP1 may be reflected by the sample 180 to generate first reflected light RL1, and the second input polarization component IP2 may be reflected by the sample 180 to generate second reflected light RL2. Similar to the case where the first input light IL1 is generated, when the second input light IL2 is generated from the second point light source 152, reflected light RL including third reflected light (not shown) and fourth reflected light (not shown) may be generated from the third input polarization component IP3 and the fourth input polarization component IP4, respectively.

According to example embodiments, the first reflected light RL1 and the second reflected light RL2 may pass through the second relay lens 170 and be transmitted to the meta surface structure 160. The meta surface structure 160 may be configured to separate the first reflected light RL1 into a first reflected polarization component RP1 and a second reflected polarization component RP2 and separate the second reflected light RL2 into a third reflected polarization component RP3 and a fourth reflected polarization component RP4.

The polarization separation of the input light IL by the meta surface structure 160, described with reference to FIGS. 5 to 6C, may also be applied in the same way to the first reflected light RL1 and the second reflected light RL2 transmitted to the meta surface structure 160. For example, the first reflected polarization component RP1 and the second reflected polarization component RP2 may have different wavenumbers and different phase gradients. For example, the third reflected polarization component RP3 and the fourth reflected polarization component RP4 may have different wavenumbers and different phase gradients independently of the first reflected polarization component RP1 and the second reflected polarization component RP2. For example, the first to fourth reflected polarization components RP1, RP2, RP3, and RP4 may each independently represent a Fourier spectrum in the Fourier domain and provide pieces of optical information independent of each other.

In some embodiments, similar to the case where the first input light IL1 is generated, when the second input light IL2 is generated from the second point light source 152, the third reflected light (not shown) may pass through the meta surface structure 160 and be separated into a fifth reflected polarization component (not shown) and a sixth reflected polarization component (not shown), and the fourth reflected light (not shown) may pass through the meta surface structure 160 and be separated into a seventh reflected polarization component (not shown) and an eighth reflected polarization component (not shown).

In the semiconductor measurement device 100 according to some example embodiments, the meta surface structure 160 may be in the path of the first input light IL1, the path of the second input light IL2, and the path of the reflected light RL. According to example embodiments, four reflected polarization components may be generated from one point light source of the semiconductor measurement device 100. For example, the first to fourth reflected polarization components RP1, RP2, RP3, and RP4 may be generated from the first input light IL1 generated from one first point light source 112. For example, fifth to eighth reflected polarization components (not shown) may be generated from the second input light IL2 generated from one second point light source 152.

According to some example embodiments, the first to fourth reflected polarization components RP1, RP2, RP3, and RP4 may be transmitted to the objective lens 140. The first to fourth reflected polarization components RP1, RP2, RP3, and RP4 refracted by the objective lens 140 may be parallel light, but are not limited thereto.

According to example embodiments, the first to fourth reflected polarization components RP1, RP2, RP3, and RP4 may be transmitted to the beam splitter 130. According to example embodiments, the beam splitter 130 may be configured to transmit the first to fourth reflected polarization components RP1, RP2, RP3, and RP4. According to example embodiments, the first to fourth reflected polarization components RP1, RP2, RP3, and RP4 may be transmitted from the beam splitter 130 to the detector 190. For example, the first to fourth reflected polarization components RP1, RP2, RP3, and RP4 may be transmitted to the image sensor 194 through the tube lens 192. For example, the beam splitter 130 may transmit light incident from the first relay lens 120 to the objective lens 140 and may transmit, to the tube lens 192, light reflected from the sample 180 and incident through the objective lens 140.

In some embodiments, the tube lens 192 directs the light reflected from the sample 180 to an image sensor 194; the image sensor 194 may include a charge-coupled device (CCD) camera, a complementary metal-oxide-semiconductor (CMOS) image sensor, and/or the like, but is not limited thereto.

According to example embodiments, the processor 196 may be connected to the first light source unit 110, the second light source unit 150, and the image sensor 194. According to example embodiments, the processor 196 may be configured to control the generation of the pieces of first input light IL1 independently from each other from the plurality of first point light sources 112 of the first light source unit 110 and to control the generation of the pieces of second input light IL2 independently from each other from the plurality of second point light sources 152 of the second light source unit 150. According to example embodiments, the processor 196 may be configured to perform Fourier ptychography-based imaging, e.g., by matching information about the incident angles of the pieces of first input light IL1 and/or the pieces of second input light IL2, obtained based on information about the positions of the plurality of first point light sources 112 and the plurality of second point light sources 152, to a signal of a reflected polarization component detected from each input light. In some embodiments, the processor 196 may be configured to calculate and generate an amplitude image and a phase image based on the detected reflected polarization component, and may be configured to perform a Fourier ptychography-based algorithm through the amplitude image and the phase image and restore an image. The processor 196 may include (and/or be implemented by) processing circuitry including hardware, software, or a combination of hardware and software. For example, the processing circuitry more specifically may include, but is not limited to, a central processing unit (CPU), a neural processing unit (NPU), a graphics processing unit (GPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

FIG. 7 is a diagram illustrating an optical system simulation method of the semiconductor measurement device 100 according to some example embodiments. Specifically, FIG. 7 shows an amplitude image and a phase image, which are obtained from each of the first to fourth reflected polarization components RP1, RP2, RP3, RP4 obtained from one input light, for example, the first input light IL1, and an optical system simulated from the amplitude image and the phase image.

The objective lens 140 of the semiconductor measurement device 100 according to some example embodiments may have a relatively low numerical aperture and have a wide field of view (FoV). The meta surface structure 160 may be configured to generate a difference in a detection signal by providing a phase delay difference for each polarization, and the semiconductor measurement device 100 may restore images having high resolution while having a wide FoV, based on detailed optical information obtained through a plurality of segmented reflected polarization components. For example, the semiconductor measurement device 100 may provide an image having improved space bandwidth product (SBP). In addition, the separation of polarization components added to various incident angles may provide not only detailed information about the three-dimensional structure of a semiconductor surface to be measured, but also information about materials constituting the semiconductor surface, such as stress information.

The meta surface structure 160 of the semiconductor measurement device 100 according to some example embodiments may simultaneously provide polarization and phase delay to the input light IL and the reflected light RL through the plurality of meta atoms 164, and thus, detailed optical information may be obtained without multiple polarizers. The measurement device according to the comparative example, which includes a polarizer, requires a polarization camera, and the polarization camera not only has a lower extinction ratio compared to the polarizer, but also uses a method of splitting pixels, which is disadvantageous in terms of image resolution. In addition, optical information obtained through a polarizer and a polarization camera includes an optical axis but may not provide specific information about components of the Jones matrix or Mueller matrix. In the semiconductor measurement device 100 according to some example embodiments, specific components of the Jones matrix or Miller matrix may be obtained from the reflected polarization components without the need to use a separate polarizer or polarization camera, and high-resolution images may be restored using a Fourier ptychography-based algorithm.

In addition, the phase for any polarization pair may be adjusted from any plurality of meta atoms 164, and the meta surface structure 160, which is optimized for measuring the characteristics of a desired measurement target, for example, three-dimensional structure or physical properties, may be reverse designed to give a desired phase gradient to any polarization pair.

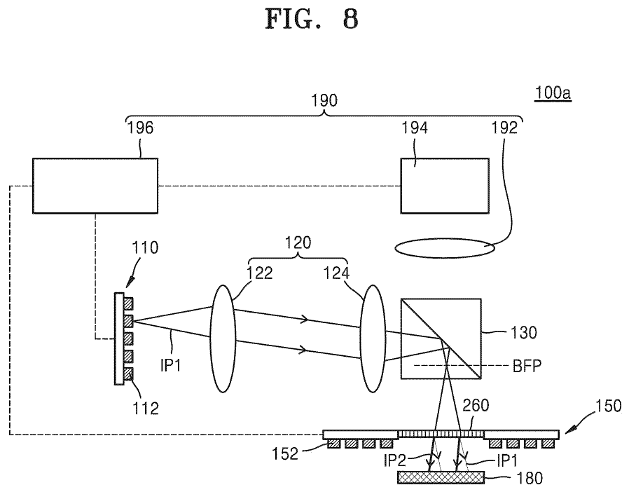

FIG. 8 is a schematic structural diagram illustrating a measurement device 100a according to some other embodiments. In FIG. 8, the same reference numerals as in FIGS. 1 to 7 indicate the same members, and duplicate descriptions thereof are omitted.

The measurement device 100a illustrated in FIG. 8 includes substantially the same (or a similar) configuration as the semiconductor measurement device 100 described with reference to FIGS. 1 to 7. However, in the measurement device 100a, the second relay lens 170 is omitted and a meta surface structure 260 is included instead of the objective lens 140 and the meta surface structure 160.

According to some example embodiments, the second light source unit 150 may be disposed around the meta surface structure 260 and may have a ring shape in a plan view and be disposed to surround the meta surface structure 260.

According to some example embodiments, the meta surface structure 260 may be configured to separate input light for each polarization and provide a phase gradient, similar to the meta surface structure 160 described with reference to FIGS. 1 to 7. However, the meta surface structure 260 may be configured to collimate and pass the input light. In the present specification, the meta surface structure 260 may also be referred to as a meta lens.

According to some example embodiments, the first input light IL1 from the beam splitter 130 may be transmitted to the meta surface structure 260. According to some example embodiments, the meta surface structure 260 may be configured to separate the first input light IL1 into a first input polarization component IP1 and a second input polarization component IP2. The first input polarization component IP1 and the second input polarization component IP2 may each be parallel light. In some embodiments, the meta surface structure 260 may have a back focal plane BFP between the meta surface structure 260 and the first relay lens 120.

According to some example embodiments, the first input polarization component IP1 and the second input polarization component IP2 may each be transmitted to the sample 180, and may be reflected from the sample 180 to generate reflected light RL, as described with reference to FIG. 3C. For example, the reflected light RL may include a first reflected light RL1 and a second reflected light RL2 and may be transmitted to the meta surface structure 260. The first reflected light RL1 may be separated into a first reflected polarization component RP1 and a second reflected polarization component RP2 through the meta surface structure 260, and the second reflected light RL2 may be separated into a third reflected polarization component RP3 and a fourth reflected polarization component RP4 through the meta surface structure 260.

According to some example embodiments, the meta surface structure 260 may not be on the path of the second input light IL2 generated from the plurality of second point light sources 152 of the second light source unit 150. For example, the second input light IL2 may be directly transmitted to the sample 180 and may be reflected from the sample 180 to generate reflected light RL. The reflected light RL may be transmitted to the meta surface structure 260 and separated into two reflected polarization components (not shown).

The first to fourth reflected polarization components RP1, RP2, RP3, and RP4 generated from one first input light IL1 and two reflected polarization components (not shown) generated from one second input light IL2 may be transmitted to the detector 190, and the processor 196 may be configured to perform imaging based on optical information obtained from the reflected polarization components.

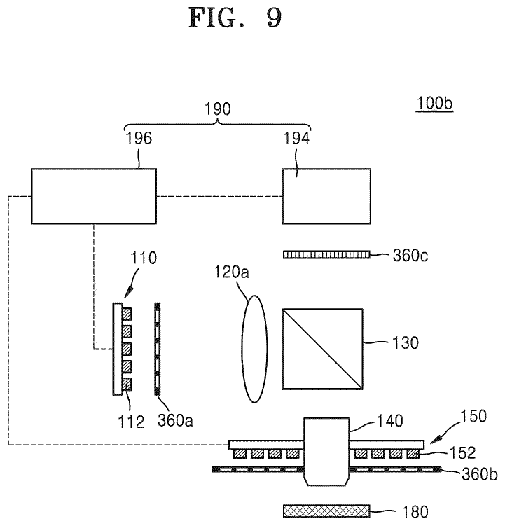

FIG. 9 is a schematic structural diagram illustrating a measurement device 100b according to some other embodiments. In FIG. 9, the same reference numerals as in FIGS. 1 to 8 indicate the same members, and duplicate descriptions thereof are omitted.

The semiconductor measurement device 100b illustrated in FIG. 9 may include a first light source unit 110, a first meta surface structure 360a, an auxiliary lens 120a, a beam splitter 130, an objective lens 140, a second light source unit 150, a second meta surface structure 360b, a third meta surface structure 360c, an image sensor 194, and a processor 196.

According to example embodiments, the first to third meta surface structures 360a, 360b, and 360c may each be configured to separate input light for each polarization and provide a phase gradient, similar to the meta surface structure 160 described with reference to FIGS. 1 to 7. The light input to the first to third meta surface structures 360a, 360b, and 360c may be separated for each polarization and have independent Fourier spectra in the Fourier domain.

According to example embodiments, at least some of the first to third meta surface structures 360a, 360b, and 360c may be configured to condense input light.

According to example embodiments, the first meta surface structure 360a may be in the path of the first input light IL1 from the first light source unit 110 and may be configured to condense the first input light IL1. In some embodiments, the first meta surface structure 360a may include a plurality of micro meta lenses having different focal lengths. In some embodiments, the focal lengths of input polarization components separated from at least some of the pieces of first input light IL1 through the first meta surface structure 360a may be different from the focal lengths of input polarization components separated from some other of the pieces of first input light IL1 through the first meta surface structure 360a. However, even in this case, a first input polarization component (not shown) and a second input polarization component (not shown), separated from one first input light IL1, may have the same focal distance.

The first input polarization component and the second input polarization component from the first meta surface structure 360a may be transmitted to the beam splitter 130 through the auxiliary lens 120a. The beam splitter 130 may be configured to reflect the first and second input polarization components and transmit the reflected first and second input polarization components to the objective lens 140.

According to example embodiments, the objective lens 140 may be configured to collimate the first input polarization component and the second input polarization component and may be configured to transmit the first input polarization component and the second input polarization component from the beam splitter 130 to the sample 180. The first input polarization component and the second input polarization component may be reflected by the sample 180 to generate reflected light RL, and the reflected light RL may be transmitted to the beam splitter 130 through the objective lens 140. For example, the reflected light RL may include first reflected light and second reflected light generated from the first input polarization component and the second input polarization component, respectively. The beam splitter 130 may be configured to transmit the reflected light RL, and the reflected light RL may be transmitted to the third meta surface structure 360c. In some embodiments, the first reflected light of the reflected light RL may be separated into a first reflected polarization component (not shown) and a second reflected polarization component (not shown) through the third meta surface structure 360c, and the second reflected light may be separated into a third reflected polarization component (not shown) and a fourth reflected polarization component (not shown). The first to fourth reflected polarization components may be transmitted to the image sensor 194 and detected by the image sensor 194.

According to example embodiments, the second meta surface structure 360b may overlap the second light source unit 150 and may be arranged to surround the objective lens 140. According to example embodiments, the second meta surface structure 360b may be on the path of the second input light IL2 and may be configured to separate the second input light IL2 into the third input polarization component (not shown) and the fourth input polarization component (not shown).

According to example embodiments, the third input polarization component and the fourth input polarization component may be transmitted to the sample 180. The third input polarization component and the fourth input polarization component may be reflected from the sample 180 to generate reflected light RL, and the reflected light RL may include third reflected light from the third input polarization component and fourth reflected light from the fourth input polarization component. The reflected light RL may be transmitted to the beam splitter 130 through the objective lens 140. The beam splitter 130 may be configured to transmit the reflected light RL, and the reflected light RL may be transmitted to the third meta surface structure 360c. In some embodiments, the third reflected light of the reflected light RL may be separated into a fifth reflected polarization component (not shown) and a sixth reflected polarization component (not shown) through the third meta surface structure 360c, and the fourth reflected light may be separated into a seventh reflected polarization component (not shown) and an eighth reflected polarization component (not shown). The fifth to eighth reflected polarization components may be transmitted to the image sensor 194 and detected by the image sensor 194.

In some embodiments, at least one of the first meta surface structure 360a, the second meta surface structure 360b, and/or the third meta surface structure 360c may include a plurality of micro meta lenses. For example, subsets of the plurality of micro meta lenses may have different focal lengths. Accordingly, light integration efficiency may be improved by performing different polarization optimizations on point light sources.

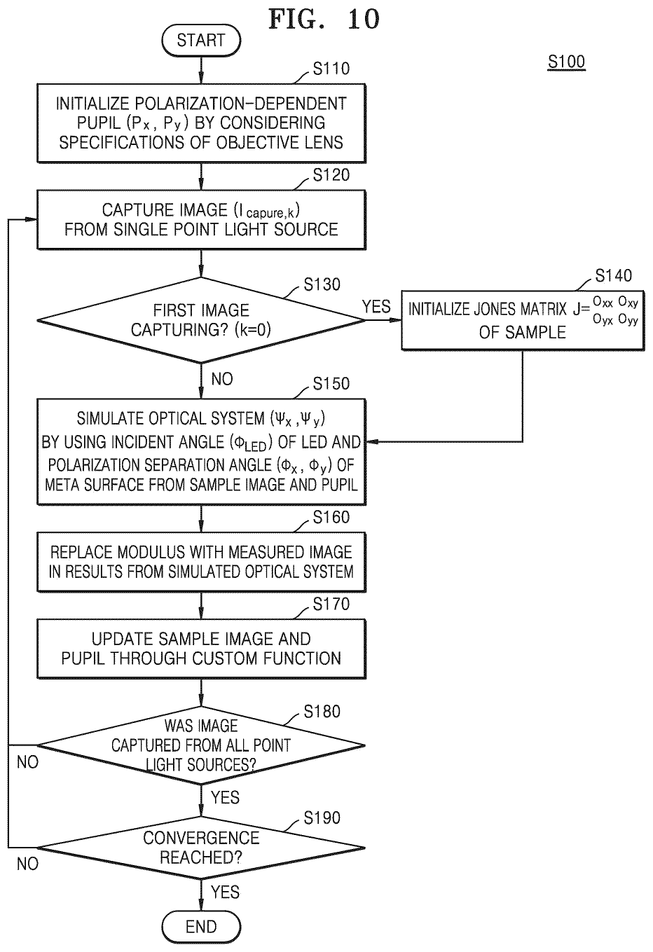

Below, with reference to FIG. 10, a measurement method using the semiconductor measurement devices 100, 100a, and 100b described with reference to FIGS. 1 to 9 will be described.

FIG. 10 is a flowchart illustrating a measurement method S100 according to example embodiments. In the following description, the same reference numerals as in FIGS. 1 to 8 indicate the same members, and duplicate descriptions thereof are omitted.

According to example embodiments, a polarization-dependent pupil (Pₓ, P_{y}) may be initialized considering the specifications of the objective lens 140 (operation S110). Below, the measurement method S100 will be described as an example of orthogonal line polarization, but the inventive concepts are not limited thereto.

Thereafter, an image may be captured from a single point light source (operation S120). The single point light source refers to one of the plurality of first point light sources 112 and one of the plurality of second point light sources 152. An image (I_{capure,k}) may be generated by generating input light from the single point light source and detecting a reflected component.

Thereafter, it may be determined whether the above-described image capturing was performed for the first time (operation S130). When an image is first generated, a Jones matrix may be initialized using the image as a sample image (operation S140), and the Jones matrix may be expressed as Equation 1 below.

$$J = [ \begin{matrix}{O}_{xx} & {O}_{xy} \\ {O}_{yx} & {O}_{yy}\end{matrix} ] \qquad [ Equation 1 ]$$

In Equation 1 above, Oₓₓ represents a signal to be detected when the input light IL is x-polarized through the meta surface structure 160 and then reflected from the sample 180 and x-polarized. Oxy represents a signal to be detected when the input light IL is y-polarized through the meta surface structure 160 and then reflected from the sample 180 and x-polarized, and O_{yx} represents a signal to be detected when the input light IL is x-polarized through the meta surface structure 160 and then reflected from the sample 180 and y-polarized. O_{yy} represents a signal to be detected when the input light IL is y-polarized through the meta surface structure 160 and then reflected from the sample 180 and y-polarized.

Thereafter, an optical system may be simulated through Equation 2 below by using an incident angle (ϕ_{LED}) and polarization separation angle (ϕₓ, ϕ_{y}) of the input light IL from the sample image and pupil (operation S150). Here, the polarization separation angle (ϕₓ, ϕ_{y}) may correspond to the phase gradient angle θₚ described with reference to FIG. 6.

$${Ψ}_{x} = {F}^{- 1} ( F ( {O}_{xx} exp ( j ( {φ}_{L E D} + 2 {φ}_{x} ) ) + F ( {O}_{x γ} exp ( j ( {φ}_{L E D} + {φ}_{x} + {φ}_{y} ) ) ) {P}_{x} ) \qquad [ Equation 2 ]$$

$${Ψ}_{y} = {F}^{- 1} ( F ( {O}_{yy} exp ( j ( {φ}_{L E D} + 2 {φ}_{y} ) ) + F ( {O}_{yx} exp ( j ( {φ}_{L E D} + {φ}_{x} + {φ}_{y} ) ) ) {P}_{Y} )$$

Thereafter, a modulus may be replaced with the measured image based on the simulated optical system and the sample image (I_{capure,k}) through Equation 3 below (operation S160).

$${Ψ}_{x}^{′} = {Ψ}_{x} \times ( {I}_{k} \div ( {\vert {Ψ}_{x} \vert}^{2} + {\vert {Ψ}_{y} \vert}^{2} ) ) , {Ψ}_{y}^{′} = {Ψ}_{y} \times ( {I}_{k} \div ( {\vert {Ψ}_{x} \vert}^{2} + {\vert {Ψ}_{y} \vert}^{2} ) ) \qquad [ Equation 3 ]$$

Thereafter, the sample image (Iₖ) and the pupil (Pₓ, P_{y}) may be updated through a custom function in Equation 4 below (operation S170).

$${O}_{xx} = {α}_{x} \times {P}_{x}^{*} \times ( {Ψ}_{x}^{′} - {Ψ}_{x} ) \div ( {\vert {P}_{x} \vert}^{2} + {δ}_{1} ) , \qquad [ Equation 4 ]$$

$${O}_{yy} = {α}_{y} \times {P}_{y}^{*} \times ( {Ψ}_{y}^{′} - {Ψ}_{y} ) \div ( {\vert {P}_{y} \vert}^{2} + {δ}_{1} )$$

$${O}_{xy} = {O}_{yx} = {α}_{xy} \times ( {P}_{x}^{*} \times ( {Ψ}_{x}^{′} - {Ψ}_{x} ) \div ( {\vert {P}_{x} \vert}^{2} + {δ}_{1} ) + {P}_{y}^{*} \times ( {Ψ}_{y}^{′} - {Ψ}_{y} ) \div ( {\vert {P}_{y} \vert}^{2} + {δ}_{1} ) )$$

$${P}_{x} = {β}_{x} \times {O}_{xx}^{*} \times ( {Ψ}_{x}^{′} - {Ψ}_{x} ) \div ( {\vert {O}_{xx} \vert}^{2} + {δ}_{1} ) ,$$

$${P}_{y} = {β}_{y} \times {O}_{yy}^{*} \times ( {Ψ}_{y}^{′} - {Ψ}_{y} ) \div ( {\vert {O}_{yy} \vert}^{2} + {δ}_{1} )$$

In Equation 4 above, O_{yx} is illustrated as being the same as Oxy. For example, when input light is separated into pieces of linearly polarized light by the meta surface structure 160, Oxy and O_{yx} are expressed by the same formula. In Equation 4 above, αₓ, α_{y}, α_{xy}, βₓ, β_{y}, and δ₁ are parameters for correction and may be designed according to the structure and physical properties of a target measurement object.

Thereafter, it may be determined whether an image was captured from all point light sources (operation S180). According to example embodiments, when an image was not captured from all point light sources, operation S120 may be performed again, and thus, the image may be captured from one (e.g., another) point light source selected from the plurality of point light sources 112 and 115.

When the captured image is not the first captured image, the optical system may be simulated again from a corrected sample image (Iₖ) and a corrected pupil (Pₓ, P_{y}) in operation S150, and operation S160 and operation S170 may be sequentially performed again.

When the series of processes described above are repeatedly performed until the image is captured from all point light sources, it may be determined whether convergence has been reached (operation S190). Whether convergence has been reached may be determined through Equation 5 below.

$$C = {Σ ( {I}_{p r e d} - {I}_{real} )}^{2} < 10 {-}^{5} \qquad [ Equation 5 ]$$

In Equation 5, I_{pred} is a final corrected and restored sample image, and Iᵣₑₐₗ represents an actual image. C in Equation 5 is an exemplary value (e.g., a target value), and the specific value may vary depending on the purpose and object of measurement.

In some embodiments, when it is determined that C has not reached convergence, I_{pred} may be updated by performing additional calculations based on possessed pieces of polarization information by using the fact that measured images have structural similarities to each other. For example, a structural similarity index measure may be calculated based on the possessed pieces of polarization information, and calculations and updates may be performed in the direction of increasing the structural similarity through gradient descent. The calculations and updates may be performed until it is determined that C has reached convergence, and the updates may be terminated when it is determined that C has reached convergence.

In some other embodiments, when it is determined that C has not reached convergence, the image may be captured again from a single point light source in operation S120. However, in this case, because the single point light source is the first selected point light source among a plurality of point light sources but the calculated image is not the first image captured, it is possible to proceed to operation S150 and the series of processes described above may be repeated until C in Equation 5 converges. When it is determined that C has reached convergence, the measurement may be terminated.

While the inventive concepts have been particularly shown and described with reference to embodiments thereof, it will be understood that various changes in form and details may be made therein without departing from the spirit and scope of the following claims.

What is claimed is:

1. A semiconductor measurement device comprising:
a first light source unit including a plurality of first point light sources configured to generate a first input light;
a first relay lens in a path of the first input light;
an objective lens in a path of the first input light having passed through the first relay lens, the objective lens configured to make the first input light incident to a sample;
a meta surface structure in a path of the first input light having passed the objective lens, the meta surface structure configured to separate the first input light into a first input polarization component and a second input polarization component, to separate first reflected light, generated when the first input polarization component is reflected by the sample, into a first reflected polarization component and a second reflected polarization component, and to separate second reflected light, generated when the second input polarization component is reflected by the sample, into a third reflected polarization component and a fourth reflected polarization component; and
a detector configured to detect the first reflected polarization component, the second reflected polarization component, the third reflected polarization component, and the fourth reflected polarization component.

2. The semiconductor measurement device of claim 1, wherein the first relay lens includes a first lens and a second lens sequentially in the path of the first input light, and
wherein the first lens is configured to collimate the first input light.

3. The semiconductor measurement device of claim 1, wherein the objective lens is configured to collimate the first input light.

4. The semiconductor measurement device of claim 1, wherein the objective lens is configured to have a back focal plane between the objective lens and the first relay lens.

5. The semiconductor measurement device of claim 1, further comprising:
a second light source unit around the objective lens and the second light source unit including a plurality of second point light sources configured to generate second input light having an incident angle with respect to the sample,
wherein the incident angle of the second input light is different from an incident angle of the first input light with respect to the sample, and
wherein the meta surface structure is in a path of the second input light between the second light source unit and the sample.

6. The semiconductor measurement device of claim 5, wherein the meta surface structure is further configured to separate the second input light into a third input polarization component and a fourth input polarization component.

7. The semiconductor measurement device of claim 6, wherein the meta surface structure is further configured to separate third reflected light, generated when the third input polarization component is reflected by the sample, into a fifth reflected polarization component and a sixth reflected polarization component, and to separate fourth reflected light, generated when the fourth input polarization component is reflected by the sample, into a seventh reflected polarization component and an eighth reflected polarization component.

8. The semiconductor measurement device of claim 1, further comprising:
a second relay lens between the meta surface structure and the sample,
wherein the meta surface structure is conjugate with the sample with the second relay lens therebetween.

9. The semiconductor measurement device of claim 1, wherein the meta surface structure is configured to provide a phase gradient to the first input light, the first reflected light, and the second reflected light.

10. The semiconductor measurement device of claim 9, wherein the meta surface structure is configured to provide the phase gradient independently to each of the first input light, the first reflected light, and the second reflected light.

11. A semiconductor measurement device comprising:
a first light source unit including a plurality of first point light sources configured to generate first input light;
a first relay lens in a path of the first input light;
a meta surface structure configured to transmit the first input light having passed through the first relay lens to a sample and to separate the first input light into a first input polarization component and a second input polarization component; and
a second light source unit around the meta surface structure, the second light source unit including a plurality of second point light sources configured to generate second input light having an incident angle with respect to the sample, the incident angle of the second input light being different from an incident angle of the first input light with respect to the sample.

12. The semiconductor measurement device of claim 11, wherein the meta surface structure is further configured to separate first reflected light, generated when the first input polarization component is reflected by the sample, into a first reflected polarization component and a second reflected polarization component, and separate second reflected light, generated when the second input polarization component is reflected by the sample, into a third reflected polarization component and a fourth reflected polarization component.

13. The semiconductor measurement device of claim 12, further comprising:
a beam splitter configured to reflect, toward the sample, the first input light having passed through the first relay lens and to transmit the first reflected polarization component, the second reflected polarization component, the third reflected polarization component, and the fourth reflected polarization component.

14. The semiconductor measurement device of claim 11, wherein the meta surface structure is further configured to separate third reflected light, generated when the second input light is reflected by the sample, into a fifth reflected polarization component and a sixth reflected polarization component.

15. The semiconductor measurement device of claim 11, wherein the meta surface structure is further configured to collimate the first input light.

16. The semiconductor measurement device of claim 1, wherein the meta surface structure is configured to provide a phase gradient such that the first input polarization component has a first phase gradient angle with respect to the first input light, and the second input polarization component has a second phase gradient angle with respect to the first input light.

17. The semiconductor measurement device of claim 16, wherein the meta surface structure is configured to provide the phase gradient such that the first phase gradient angle is different from the second phase gradient angle.

18. A semiconductor measurement device comprising:
a first light source unit including a plurality of first point light sources spaced apart from each other and each configured to generate first input light;
a first relay lens in a path of the first input light;
an objective lens configured to collimate the first input light having passed through the first relay lens and make the collimated first input light incident to a sample;
a second light source unit around the objective lens and including a plurality of second point light sources each configured to generate second input light having an incident angle with respect to the sample, the incident angle of the second input light being different from an incident angle of the first input light with respect to the sample;
a meta surface structure in the path of the first input light having passed through the objective lens and a path of the second input light such that the meta surface structure is configured to separate the first input light into a first input polarization component and a second input polarization component, to separate the second input light into a third input polarization component and a fourth input polarization component, to separate first reflected light, generated when the first input polarization component is reflected by the sample, into a first reflected polarization component and a second reflected polarization component, and to separate second reflected light, generated when the second input polarization component is reflected by the sample, into a third reflected polarization component and a fourth reflected polarization component; and
a detector configured to detect the first reflected polarization component, the second reflected polarization component, the third reflected polarization component, and the fourth reflected polarization component.

19. The semiconductor measurement device of claim 18, wherein the meta surface structure includes:
a transparent substrate; and
a plurality of meta atoms on the transparent substrate,
wherein the plurality of meta atoms each include at least one of titanium dioxide (TiO), gallium nitride (GaN), silicon nitride (SiN), or silicon (Si).

20. The semiconductor measurement device of claim 18, wherein the meta surface structure is configured to provide a phase gradient to each of the first input light and the second input light.
